(19) United States
(12) Patent Application Publication
(10) Pub. No.: US 2024/0178660 A1
(43) Pub. Date: May 30, 2024

(54) SURGE PROTECTION DEVICE

(71) Applicant: AIXlink Ltd., Chengdu City (CN)

(72) Inventor: Chih-Cheng LIN, Hsinchu City (TW)

(73) Assignee: AIXlink Ltd., Chengdu City (CN)

(21) Appl. No.: 18/172,354

(22) Filed: Feb. 22, 2023

(30) Foreign Application Priority Data
Nov. 28, 2022 (CN) 202211500530.3

(51) Int. Cl. H02H 9/04; G01R 19/165

(52) U.S. Cl. CPC H02H 9/042; G01R 19/16571

(57) ABSTRACT

Disclosed is a surge protection device, including a power input port connecting a voltage source, a power output port connecting a load, a switching element connecting the power output port, a voltage measurement circuit connecting the power input port, a processing circuit, and a switch control circuit. The voltage measurement circuit generates a voltage measurement signal based on an input voltage signal of the voltage source. When the processing circuit determines that the input voltage signal is in a normal state based on the voltage measurement signal, it controls the switching element to be turned on, to make the voltage source supply power to the load. The switch control circuit compares the voltage measurement signal with a voltage threshold, to control the switching element to be turned off when it determines that the input voltage signal is in a surge state, so that the power output port is powered off.

### CROSS-REFERENCE TO RELATED APPLICATION

This application claims the priority benefit of Chinese Patent Application Serial Number 202211500530.3, filed on Nov. 28, 2022, the full disclosure of which is incorporated herein by reference.

### BACKGROUND

### Technical Field

The present disclosure relates to the technical field of power supply circuit protection, and particularly to a surge protection device.

### Related Art

The generation of surge easily causes the load damage and the circuit aging. Therefore, in the prior art, surge absorbing elements, such as gas discharge tubes (GDTs), transient voltage suppressors (TVSs) and metal oxide varistors (MOVs), are usually used to avoid or reduce the damage to loads caused by surges.

However, the circuit using the GDT to suppress the surge has the problems that it responds slowly to surges, the GDT is easily damaged, and it has no function of jointly controlling the load; the circuit using the MOV to suppress the surge has the problems that it has incomplete effect on surge suppression, the MOV is easy to age, and it has no function of jointly controlling the load; and the circuit using the TVS to suppress the surge has the problems that it is expensive, the TVS has an insufficient voltage tolerance, and it has no function of jointly controlling the load.

Therefore, how to provide a solution to the above-mentioned technical problem is a problem that those skilled in the art need to solve at present.

### SUMMARY

The embodiments of the present disclosure provide a surge protection device, which can solve the problem that the circuit using the surge absorbing element to suppress the surge has no function of jointly controlling the load in the prior art.

In order to solve the above technical problems, the present disclosure is implemented as follows.

The present disclosure provides a surge protection device, which includes a power input port, a power output port, a switching element, a voltage measurement circuit, a processing circuit and a switch control circuit. The power input port is connected to a voltage source, the power output port is connected to a load, the switching element is connected to the power output port, the voltage measurement circuit is connected to the power input port, the processing circuit is connected to the voltage measurement circuit and the switching element, and the switch control circuit is connected to the voltage measurement circuit and the switching element. The voltage measurement circuit is configured to generate a voltage measurement signal based on an input voltage signal of the voltage source. The processing circuit is configured to control the switching element to be turned on when the processing circuit determines that the input voltage signal is in a normal state based on the voltage measurement signal, to make the voltage source supply power to the load. The switch control circuit includes a comparator circuit. The comparator circuit compares the voltage measurement signal with a voltage threshold to controls the switching element to be turned off when the comparator circuit determines that the input voltage signal is in a surge state, so that the power output port is powered off.

In the embodiments of the present disclosure, the surge protection device obtains the voltage measurement signal through the voltage measurement circuit. The surge protection device controls the switching element to be turned on through the processing circuit when the input voltage signal is in the normal state, so that the power output port is powered on. The surge protection device quickly determines that the voltage value of the voltage measurement signal exceeds a preset voltage value (that is, the voltage threshold) through the comparator circuit of the switch control circuit (that is, the comparator circuit quickly determines that the input voltage signal is in the surge state), and controls the switching element to be turned off, so that the power output port is powered off, so as to protect the load and prolong the service life of the load.

It should be understood, however, that this summary may not contain all aspects and embodiments of the present disclosure, that this summary is not meant to be limiting or restrictive in any manner, and that the disclosure as disclosed herein will be understood by one of ordinary skill in the art to encompass obvious improvements and modifications thereto.

### BRIEF DESCRIPTION OF THE DRAWINGS

The features of the exemplary embodiments believed to be novel and the elements and/or the steps characteristic of the exemplary embodiments are set forth with particularity in the appended claims. The Figures are for illustration purposes only and are not drawn to scale. The exemplary embodiments, both as to organization and method of operation, may best be understood by reference to the detailed description which follows taken in conjunction with the accompanying drawings in which:

FIG. 1 is a schematic diagram of a surge protection device that connects to a voltage source and a load according to an embodiment of the present disclosure;

FIG. 2 is a schematic diagram of an amplifier circuit of FIG. 1 in accordance with an embodiment;

FIG. 3 is a schematic diagram of an amplifier circuit of FIG. 1 in accordance with another embodiment;

FIG. 4 is a schematic diagram of a voltage measurement circuit of FIG. 1 in accordance with an embodiment;

FIG. 5 is a schematic diagram of a processing circuit of FIG. 1 in accordance with an embodiment;

FIG. 6 is a schematic diagram of a switch control circuit of FIG. 1 in accordance with an embodiment;

FIG. 7 is a schematic diagram of a switch control circuit of FIG. 1 in accordance with another embodiment;

FIG. 8 is a schematic diagram of a surge protection device that connects to a voltage source and a load according to another embodiment of the present disclosure; and

FIG. 9 is a graph showing curves of a surge voltage and a voltage at an output terminal of a comparator circuit when a surge test is performed on the surge protection device of FIG. 1, which comprises the amplifier circuit of FIG. 2, the voltage measurement circuit of FIG. 4 and the switch control circuit of FIG. 6.

### DETAILED DESCRIPTION OF THE EMBODIMENTS

The present disclosure will now be described more fully hereinafter with reference to the accompanying drawings, in which exemplary embodiments of the disclosure are shown. This present disclosure may, however, be embodied in many different forms and should not be construed as limited to the embodiments set forth herein. Rather, these embodiments are provided so that this present disclosure will be thorough and complete, and will fully convey the scope of the present disclosure to those skilled in the art.

Certain terms are used throughout the description and following claims to refer to particular components. As one skilled in the art will appreciate, manufacturers may refer to a component by different names. This document does not intend to distinguish between components that differ in name but function.

It is to be understood that the terms “comprises”, “comprising,”, “includes” and/or “including” when used in this specification, specify the presence of stated features, integers, steps, operations, and/or components, but do not preclude the presence or addition of one or more other features, integers, steps, operations, components, and/or or any combination thereof.

Moreover, it is to be understood that when a component is referred to as being “connected” or “coupled” to another component, it can be directly connected or coupled to the other component or intervening components may be present. In contrast, when a component is referred to as being “directly connected” or “directly coupled” to another component, there are no intervening components present.

The following description is of the best-contemplated mode of carrying out the disclosure. This description is made for the purpose of illustration of the general principles of the disclosure and should not be taken in a limiting sense. The scope of the disclosure is best determined by reference to the appended claims.

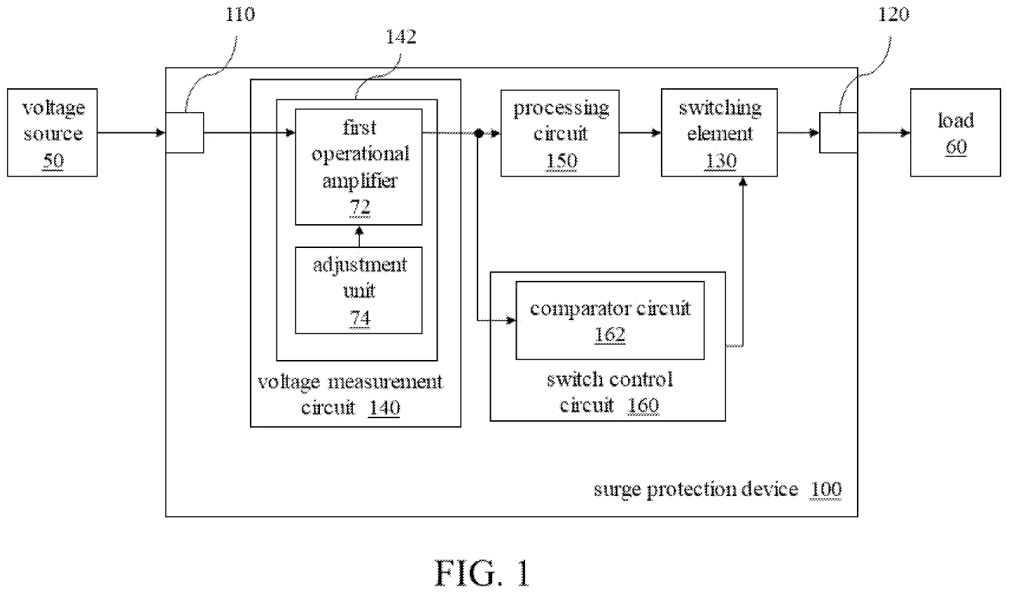

Please refer to FIG. 1, which is a schematic diagram of a surge protection device that connects to a voltage source and a load according to an embodiment of the present disclosure. As shown in FIG. 1, a surge protection device 100 comprises a power input port 110, a power output port 120, a switching element 130, a voltage measurement circuit 140, a processing circuit 150 and a switch control circuit 160. The power input port 110 is connected to a voltage source 50, the power output port 120 is connected to a load 60, the switching element 130 is connected to the power output port 120, the voltage measurement circuit 140 is connected to the power input port 110, the processing circuit 150 is connected to the voltage measurement circuit 140 and the switching element 130, and the switch control circuit 160 is connected to the voltage measurement circuit 140 and the switching element 130, wherein the load 60 may be an electronic device, such as household appliances, motors, industrial control equipment, power chargers and lamps; and the voltage source 50 may be but not limited to a commercial power supply.

The voltage measurement circuit 140 is configured to generate a voltage measurement signal based on an input voltage signal of the voltage source 50. The processing circuit 150 is configured to control the control switching element 130 to be turned on when the processing circuit 150 determines that the input voltage signal is in a normal state based on the voltage measurement signal, to make the voltage source 50 supply power to the load 60. The switch control circuit 160 comprises a comparator circuit 162, and the comparator circuit 162 is configured to compare the voltage measurement signal with a voltage threshold to control the control switching element 130 to be turned off when the comparator circuit 162 determines that the input voltage signal is in a surge state, so that the power output port 120 is powered off.

In one embodiment, the voltage measurement circuit 140, the processing circuit 150 and the switch control circuit 160 may be integrated into a single chip.

In one embodiment, the voltage measurement circuit 140 may comprise an amplifier circuit 142, the amplifier circuit 142 comprises a first operational amplifier 72 and an adjustment unit 74, and the adjustment unit 74 is connected to the first operational amplifier 72. The first operational amplifier 72 is configured to amplify the input voltage signal of the voltage source 50 which is measured. The adjustment unit 74 is configured to adjust an amplification factor of the first operational amplifier 72 to the input voltage signal of the voltage source 50 which is measured, wherein the amplification factor may be but not limited to 8, and may be adjusted according to actual needs. For example, the amplification factor may be 2, 4, 16 or 32.

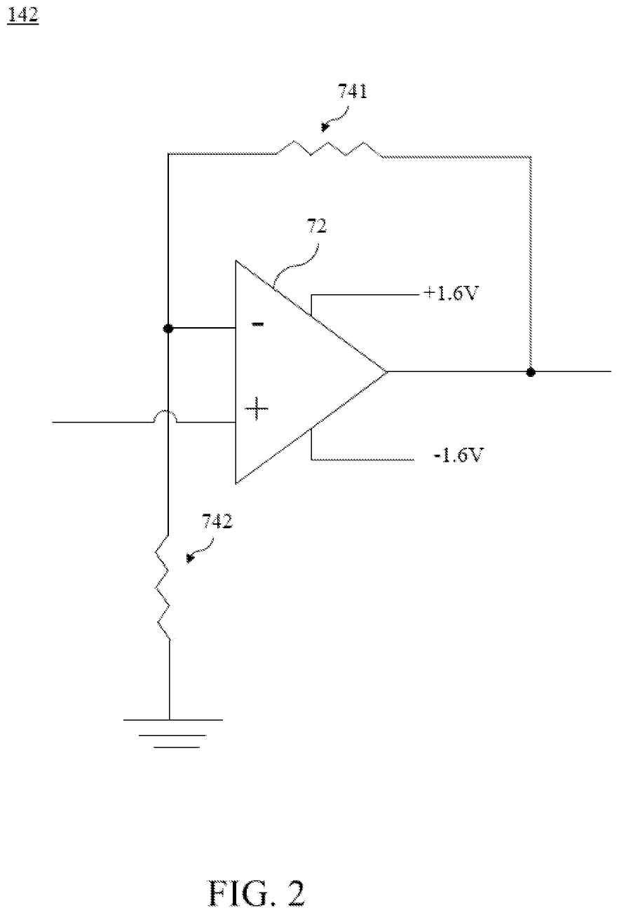

Please refer to FIG. 1 and FIG. 2, wherein FIG. 2 is a schematic diagram of an amplifier circuit of FIG. 1 in accordance with an embodiment. As shown in FIG. 1 and FIG. 2, the adjustment unit 74 may comprise a first resistor 741 and a second resistor 742, and the adjustment unit 74 adjusts the amplification factor of the first operational amplifier 72 to the input voltage signal which is measured through a resistance ratio between the first resistor 741 and the second resistor 742, one end of the first resistor 741 is connected to a negative input end of the first operational amplifier 72, the other end of the first resistor 741 is connected to an output end of the first operational amplifier 72, one end of the second resistor 742 is connected to the negative input end of the first operational amplifier 72, and the other end of the second resistor 742 is grounded, wherein the power supply voltage of the first operational amplifier 72 may be but not limited to ±1.6V, the resistance of the first resistor 741 may be but not limited to 8 kiloohms (KΩ), the resistance of the second resistor 742 may be but not limited to 1 KΩ, and the actual resistances of the first resistor 741 and the second resistor 742 can be adjusted according to requirements.

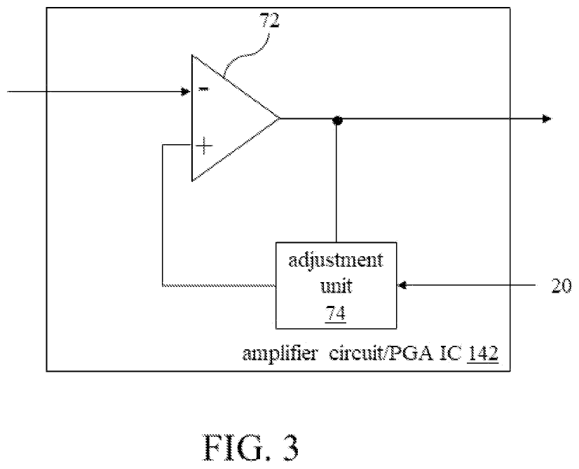

Please refer to FIG. 1 and FIG. 3, wherein FIG. 3 is a schematic diagram of an amplifier circuit of FIG. 1 in accordance with another embodiment. As shown in FIG. 1 and FIG. 3, the amplifier circuit 142 may be a programmable gain amplifier (PGA) integrated chip (IC), and the adjustment unit 74 adjusts the amplification factor of the first operational amplifier 72 to the input voltage signal which is measured based on a gain control signal 20, wherein the detailed structure of the PGA IC can refer to the existing PGA IC such as the PGA IC with the model number of TMS320F280049C and the PGA IC with the model number of PGA103, and the detail will not be described herein. The processing circuit 150 may output the gain control signal 20 to the adjustment unit 74 (that is, the processing circuit 150 controls the amplification factor of the first operational amplifier 72 to the input voltage signal of the voltage source 50 which is measured).

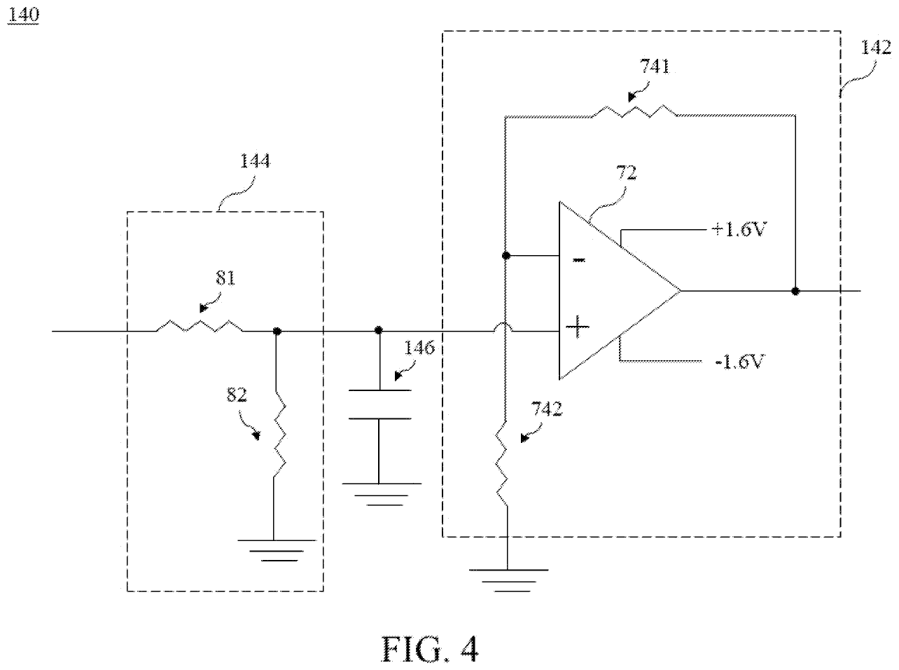

Please refer to FIG. 1 and FIG. 4, wherein FIG. 4 is a schematic diagram of a voltage measurement circuit of FIG. 1 in accordance with an embodiment. As shown in FIG. 1 and FIG. 4, the voltage measurement circuit 140 may further comprise a first voltage division circuit 144 and a capacitor 146 in addition to the amplifier circuit 142. The first voltage division circuit 144 is configured to measure the input voltage signal of the voltage source 50, wherein the first voltage division circuit 144 comprise a third resistor 81 and a fourth resistor 82, one end of the third resistor 81 is connected to the power input port 110, the other end of the third resistor 81 is connected to a positive input end of the first operational amplifier 72, one end of the fourth resistor 82 is connected to the positive input end of the first operational amplifier 72, and the other end of the fourth resistor 82 is grounded. One end of the capacitor 146 is connected to the positive input end of the first operational amplifier 72, and the other end of the capacitor 146 is grounded to reduce noise from the voltage source 50 (that is, the capacitor 146 can be used as a filter). The resistance of the third resistor 81 may be but not limited to 1 megohm (MΩ), the resistance of the fourth resistor 82 may be but not limited to 1 KΩ, the capacitance of the capacitor 146 may be but not limited to 10 nanofarads (nF), and the actual resistances of the third resistor 81 and the fourth resistor 82 and the actual capacitance of the capacitor 146 can be adjusted according to requirements.

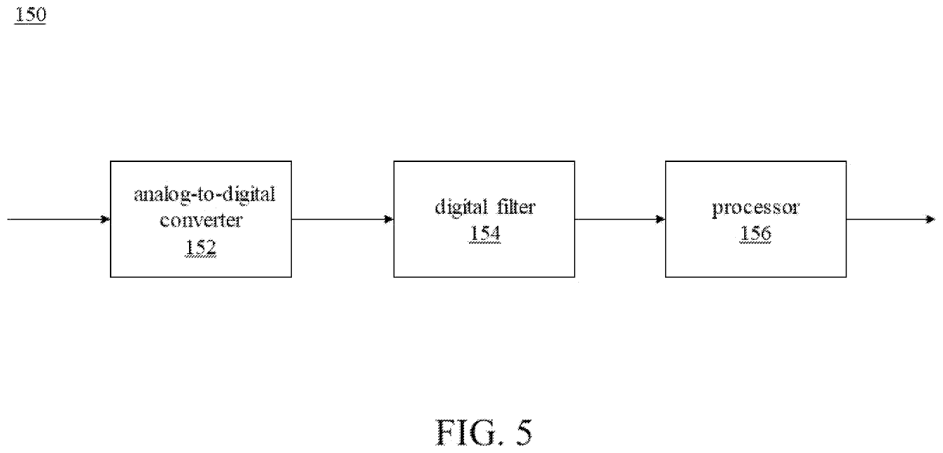

Please refer to FIG. 1 and FIG. 5, wherein FIG. 5 is a schematic diagram of a processing circuit of FIG. 1 in accordance with an embodiment. As shown in FIG. 1 and FIG. 5, the processing circuit 150 may comprise an analog-to-digital converter 152, a digital filter 154 and a processor 156, the analog-to-digital converter 152 is connected to the voltage measurement circuit 140, the digital filter 154 is connected to the analog-to-digital conversion 152, and the processor 156 is connected to the digital filter 154. The analog-to-digital converter 152 is configured to convert the voltage measurement signal into a digital voltage signal. The digital filter 154 is configured to filter noise in the digital voltage signal. The processor 156 is configured to determine whether the input voltage signal of the voltage source 50 is in the normal state or the surge state based on the digital voltage signal which is filtered. In one embodiment, when the amplifier circuit 142 is a PGA IC, the processor 156 may be further configured to output the gain control signal 20 to the adjustment unit 74.

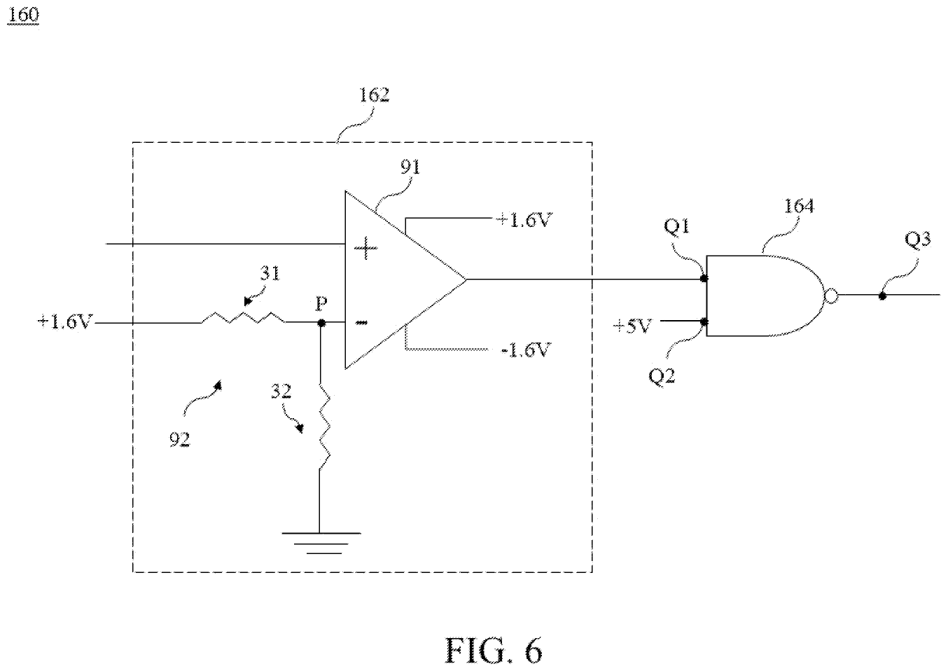

Please refer to FIG. 1 and FIG. 6, wherein FIG. 6 is a schematic diagram of a switch control circuit of FIG. 1 in accordance with an embodiment. As shown in FIG. 1 and FIG. 6, the comparator circuit 162 may comprise a second operational amplifier 91 and a second voltage division circuit 92, wherein the voltage division terminal P of the second voltage division circuit 92 is connected to a negative input end of the second operational amplifier 91 for providing a reference voltage, a positive input end of the second operational amplifier 91 is connected to the voltage measurement circuit 140. The switch control circuit 160 may further comprise a NAND gate 164, the switching element 130 is a forward relay, a first input end Q1 of the NAND gate 164 is connected to an output end of the second operational amplifier 91, a second input end Q2 of the NAND gate 164 is connected to the driving voltage (e.g., 5V) of the forward relay, and an output end Q3 of the NAND gate 164 is connected to the forward relay, wherein the power supply voltage of the second operational amplifier 91 may be but not limited to ±1.6V; the second voltage division circuit 92 may comprise a fifth resistor 31 and a sixth resistor 32, one end of the fifth resistor 31 may be connected to +1.6V, the other end of the fifth resistor 31 is connected to the negative input end of the second operational amplifier 91, one end of the sixth resistor 32 is connected to the negative input end of the second operational amplifier 91, and the other end of the sixth resistor 32 is grounded; the resistance of the fifth resistor 31 may be but not limited to 100 ohms (Q), the resistance of the sixth resistor 32 may be but not limited to 1 KΩ, and the actual resistances of the fifth resistor 31 and the sixth resistor 32 can be adjusted according to requirements.

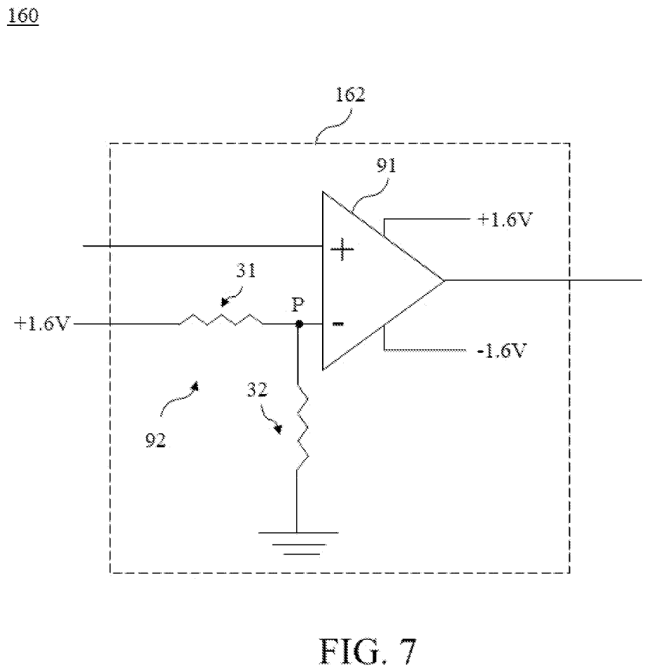

Please refer to FIG. 1 and FIG. 7, wherein FIG. 7 is a schematic diagram of a switch control circuit of FIG. 1 in accordance with another embodiment. As shown in FIG. 1 and FIG. 7, the comparator circuit 162 may comprise a second operational amplifier 91 and a second division circuit 92, wherein the voltage division terminal P of the second voltage division circuit 92 is connected to a negative input end of the second operational amplifier 91 for providing a reference voltage, a positive input end of the second operational amplifier 91 is connected to the voltage measurement circuit 140. The switching element 130 is a reverse relay, and the output end of the second operational amplifier 91 is connected to the reverse relay.

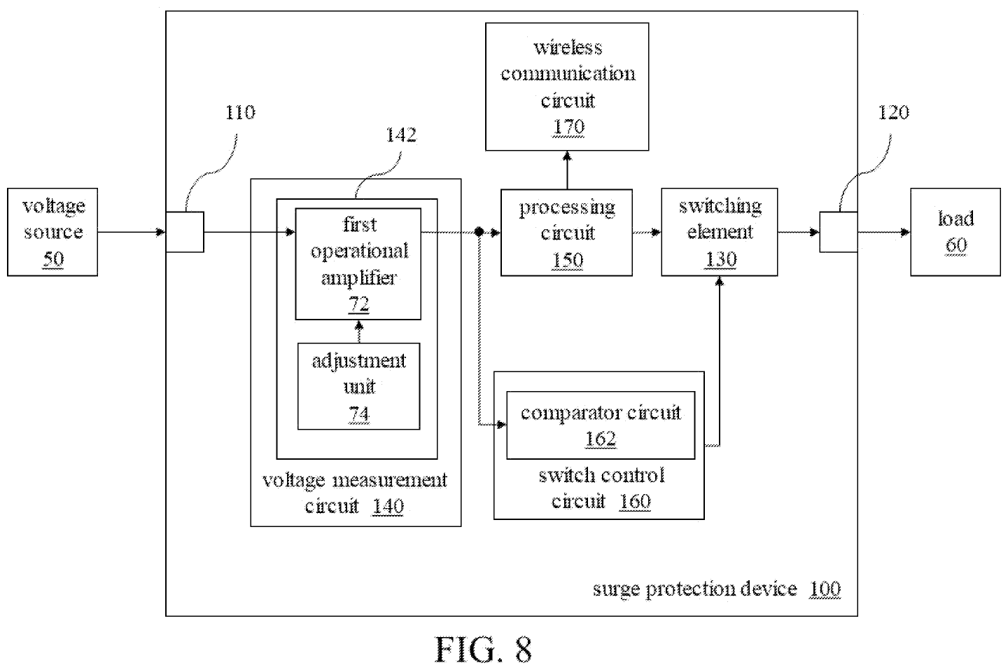

Please refer to FIG. 8, which is a schematic diagram of a surge protection device that connects to a voltage source and a load according to another embodiment of the present disclosure. As shown in FIG. 8, in addition to the power input port 110, power output port 120, the switching element 130, the voltage measurement circuit 140, the processing circuit 150 and the switch control circuit 160, a surge protection device 100 may further comprise a wireless communication circuit 170, and the wireless communication circuit 170 is connected to the processing circuit 150 and is configured to send a surge notification signal when the processing circuit 150 determines that the input voltage signal of the voltage source 50 is in a surge state based on the voltage measurement signal. The surge protection device 100 can send the surge notification signal to a terminal device of a user through the wireless communication circuit 170, to notify the user that the load 60 is suspended due to the occurrence of the surge; or the surge protection device 100 can send the surge notification signal to a cloud server, so that the cloud server records information on the occurrence of the surge.

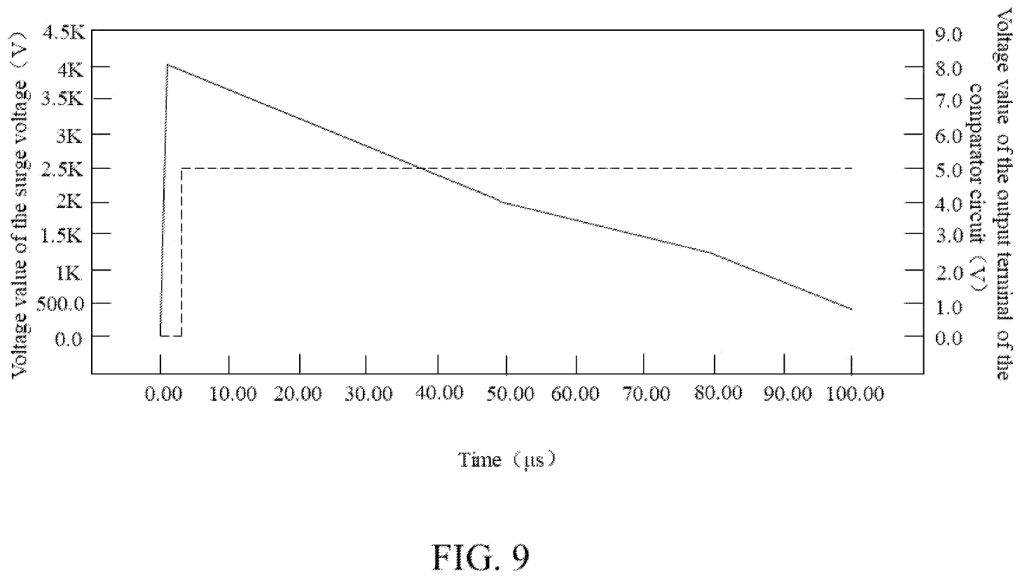

Please refer to FIG. 1, FIG. 2, FIG. 4, FIG. 6 and FIG. 9, wherein FIG. 9 is a graph showing curves of a surge voltage and a voltage at an output terminal of a comparator circuit when a surge test is performed on the surge protection device of FIG. 1, which comprises the amplifier circuit of FIG. 2, the voltage measurement circuit of FIG. 4 and the switch control circuit of FIG. 6, the left vertical axis of FIG. 9 corresponds to the voltage value of the surge voltage with the unit of volts (V), the right vertical axis corresponds to the voltage value of the output terminal of the comparator circuit with the unit of volts (V), and the horizontal axis corresponds to time with the unit of microseconds (s). A surge test is performed on the surge protection device 100 of FIG. 1, which comprises the amplifier circuit 142 of FIG. 2, the voltage measurement circuit 140 of FIG. 4 and the switch control circuit 160 of FIG. 6, to obtain the graph of FIG. 9, wherein the voltage curve corresponding to the surge voltage is shown as a solid line in FIG. 9, the maximum voltage value of the surge voltage is 4 kilovolts (KV); the voltage curve corresponding to the voltage at the output terminal of the comparator circuit 162 is shown as a dotted line in FIG. 9. When an overvoltage situation occurs, the input voltage rapidly increases and exceeds the 220 volts of the commercial power within 1 s, and the current causing damage responds within 8 s. Therefore, the surge protection device 100 needs to detect the overvoltage within 1 s, and control the switching element 130 to be turned off within 8 s. It can be seen from FIG. 9 that when an overvoltage situation occurs, the surge protection device 100, which comprises the amplifier circuit 142 of FIG. 2, the voltage measurement circuit 140 of FIG. 4 and the switch control circuit 160 of FIG. 6, can control the switching element 130 to be turned off in 3.58 s, so that the power output port 120 is powered off, which conforms to the ANSI/IEEE standard.

In summary, in the present disclosure, the surge protection device obtains the voltage measurement signal through the voltage measurement circuit. The surge protection device controls the switching element to be turned on through the processing circuit when the input voltage signal is in the normal state, so that the power output port is powered on. The surge protection device quickly determines that the voltage value of the voltage measurement signal exceeds a preset voltage value (that is, the voltage threshold) through the comparator circuit of the switch control circuit (that is, the comparator circuit quickly determines that the input voltage signal is in the surge state), and controls the switching element to be turned off, so that the power output port is powered off, so as to protect the load and prolong the service life of the load. Thus, there is no need to use the surge absorbing component, such as a GDT, a TVS and a MOV, to save costs. In addition, the voltage measurement circuit, the processing circuit and the switch control circuit can be integrated into a single chip.

Although the present disclosure has been explained in relation to its preferred embodiment, it does not intend to limit the present disclosure. It will be apparent to those skilled in the art having regard to this present disclosure that other modifications of the exemplary embodiments beyond those embodiments specifically described here may be made without departing from the spirit of the disclosure. Accordingly, such modifications are considered within the scope of the disclosure as limited solely by the appended claims.

What is claimed is:

1. A surge protection device, comprising:
a power input port, connected to a voltage source;
a power output port, connected to the load;
a switching element, connected to the power output port;
a voltage measurement circuit, connected to the power input port, and
configured to generate a voltage measurement signal based on an input voltage signal of the voltage source;
a processing circuit, connected to the voltage measurement circuit and the switching element, and configured to control the switching element to be turn on when the processing circuit determines that the input voltage signal is in a normal state based on the voltage measurement signal, to make the voltage source supply power to the load; and
a switch control circuit, connected to the voltage measurement circuit and the switching element, the switch control circuit including a comparator circuit; the comparator circuit configured to compare the voltage measurement signal with a voltage threshold, to control the switching element to be turned off when it determines that the input voltage signal is in a surge state, so that the power output port is powered off.

2. The surge protection device according to claim 1, wherein the voltage measurement circuit comprises an amplifier circuit, and the amplifier circuit comprises:
a first operational amplifier, configured to amplify the input voltage signal which is measured; and
an adjustment unit, connected to the first operational amplifier, and configured to adjust an amplification factor of the first operational amplifier to the input voltage signal which is measured.

3. The surge protection device according to claim 2, wherein the adjustment unit comprises a first resistor and a second resistor, the adjustment unit adjusts the amplification factor of the first operational amplifier to the input voltage signal which is measured through a resistance ratio between the first resistor and the second resistor, one end of the first resistor is connected to a negative input end of the first operational amplifier, the other end of the first resistor is connected to an output end of the first operational amplifier, one end of the second resistor is connected to the negative input end of the first operational amplifier, and the other end of the second resistor is grounded.

4. The surge protection device according to claim 2, wherein the amplifier circuit is a programmable gain amplifier integrated chip, the adjustment unit adjusts the amplification factor of the first operational amplifier to the input voltage signal which is measured based on a gain control signal, and the processing circuit outputs the gain control signal to the adjustment unit.

5. The surge protection device according to claim 2, wherein the voltage measurement circuit further comprises:
a first voltage division circuit, configured to measure the input voltage signal, wherein the first voltage division circuit comprises a third resistor and a fourth resistor, one end of the third resistor is connected to the power input port, the other end of the three resistor is connected to a positive input end of the first operational amplifier, one end of the fourth resistor is connected to the positive input end of the first operational amplifier, and the other end of the fourth resistor is grounded; and
a capacitor, one end of which connected to the positive input end of the first operational amplifier, and the other end of which grounded, to reduce noise from the voltage source.

6. The surge protection device according to claim 1, wherein the comparator circuit comprises a second operational amplifier and a second voltage division circuit, a voltage division terminal of the second voltage division circuit is connected to a negative input end of the second operational amplifier for providing a reference voltage, a positive input end of the second operational amplifier is connected to the voltage measurement circuit; the switch control circuit further comprises a NAND gate, the switching element is a forward relay, a first input end of the NAND gate is connected to an output end of the second operational amplifier, a second input end of the NAND gate is connected to a driving voltage of the forward relay, and an output end of the NAND gate is connected to the forward relay.

7. The surge protection device according to claim 1, wherein the comparator circuit comprises a second operational amplifier and a second voltage division circuit, a voltage division terminal of the second voltage division circuit is connected to a negative input end of the second operational amplifier for providing a reference voltage, a positive input end of the second operational amplifier is connected to the voltage measurement circuit; the switching element is a reverse relay, and an output end of the second operational amplifier is connected to the reverse relay.

8. The surge protection device according to claim 1, further comprising a wireless communication circuit, connected to the processing circuit, and configured to send a surge notification signal when the processing circuit determines that the input voltage signal is in the surge state based on the voltage measurement signal.

9. The surge protection device according to claim 1, wherein the voltage measurement circuit, the processing circuit and the switch control circuit are integrated into a single chip.

10. The surge protection device according to claim 1, wherein the processing circuit comprises:
an analog-to-digital converter, connected to the voltage measurement circuit, and configured to convert the voltage measurement signal into a digital voltage signal;
a digital filter, connected to the analog-to-digital converter, and configured to filter noise in the digital voltage signal; and
a processor, connected to the digital filter, and configured to determine whether the input voltage signal is in the normal state or the surge state based on the digital voltage signal which is filtered.
